(19) United States
(12) Patent Application Publication
(10) Pub. No.: US 2023/0105357 A1
(43) Pub. Date: Apr. 6, 2023

(54) THERMOPLASTIC LIQUID CRYSTAL POLYMER MOLDED BODY, METAL-CLAD LAMINATE, AND CIRCUIT BOARD

(71) Applicant: KURARAY CO., LTD., Kurashiki-shi (JP)

(72) Inventors: Shoma SASAKI, Kamisu-shi (JP); Takahiro NAKASHIMA, Kamisu-shi (JP); Takeshi TAKAHASHI, Kamisu-shi (JP); Shinji HIRAMATSU, Kamisu-shi (JP)

(73) Assignee: KURARAY CO., LTD., Kurashiki-shi (JP)

(21) Appl. No.: 18/064,059

(22) Filed: Dec. 9, 2022

Related U.S. Application Data
(63) Continuation of application No. PCT/JP2021/022823, filed on Jun. 16, 2021.

(30) Foreign Application Priority Data
Jun. 19, 2020 (JP) 2020-105862

(51) Int. Cl. C08G 63/02; C08J 5/18; B32B 15/09; B32B 27/36; H05K 1/03; H05K 3/02

(52) U.S. Cl. CPC C08G 63/02; C08J 5/18; B32B 15/09; B32B 27/36; H05K 1/0326; H05K 3/022; C08J 2367/00; B32B 15/20

(57) ABSTRACT

In order to maintain high haze value of thermoplastic liquid crystalline polymer while to improve total light transmittance, provided is a thermoplastic liquid crystalline polymer molded body having a haze value of 99% or higher, and a thermal expansion coefficient of 16 to 27 ppm/° C., and satisfying a correlation between a light absorption coefficient (ε) and a thickness (x) as: ε≤0.21x^{-0.55}.

### CROSS REFERENCE TO THE RELATED APPLICATION

This application is a continuation application, under 35 U.S.C. § 111(a), of international application No. PCT/JP2021/022823 filed Jun. 16, 2021, which claims priority to Japanese patent application No. 2020-105862, filed Jun. 19, 2020, the entire disclosures of all of which are herein incorporated by reference as a part of this application.

### FIELD OF THE INVENTION

The present invention relates to a thermoplastic liquid crystal polymer molded bodies having high total light transmittance and very-high haze values, the metal-clad laminates and circuit boards both using the molded bodies as substrates (base materials).

### BACKGROUND OF THE INVENTION

Thermoplastic liquid crystal polymer molded bodies have low dielectric properties (low dielectric constants and low dielectric dissipation factors) originated from properties of thermoplastic liquid crystal polymers. Thus, thermoplastic liquid crystal polymer molded bodies have attracted attention in the field of applications for which dielectric properties are regarded as important.

For example, high frequency signal technology has been developed in recent years along with increase in speed of transmission signal on printed wiring boards. In response to such developments, substrates used for printed wiring boards are required to have excellent low dielectric properties in high frequency ranges. In order to meet such requirements, thermoplastic liquid crystal polymer films with low dielectric properties have been gaining more attention in place of conventional polyimide (PI) and polyethylene terephthalate films used as substrate films for printed wiring boards.

Since thermoplastic liquid crystal polymers have high light diffusion properties (high haze values) due to an aggregation of structures called microdomains, the above-mentioned thermoplastic liquid crystal polymer molded bodies are expected to be applicable for electronic materials as well as optical materials, such as displays, light equipment, protectors for light polarizers, and anti-glare materials.

However, since thermoplastic liquid crystal polymer molded bodies have low transparency, the mold bodies are usually installed as internal parts in a device, so as not to be observed from outside. Accordingly, the thermoplastic liquid crystal polymer molded bodies have problems such as narrow flexibility for device design as well as limited designability.

Further, increasing demand for multi-layered circuit boards which can install multi-circuit wirings requires a technology to suppress misalignment of interlayer connection to connect wirings of different layers. In this regard, there has been a problem that thermoplastic liquid crystal polymer films tend to cause poor interlayer wiring connection since the information required for alignment of interlayer connection cannot be obtained sufficiently due to low transparency of the thermoplastic liquid crystal polymer film.

For example, Patent Document 1 (JP Laid-open Patent Publication No. 2005-178056) discloses a molding method of liquid crystalline polyester resin, comprising: during molding or after molding a liquid crystalline polyester resin, holding the liquid crystalline polyester resin for ten seconds or more at a temperature not lower than −20° C. of the melting temperature of the liquid crystalline polyester resin to obtain a transparent molded body having a haze value of 40% or less.

Technologies for imparting light diffusion properties while maintaining a certain transparency of the film have also been studied. For example, Patent document 2 (JP Laid-open Patent Publication No. 2007-293316) describes a light diffusing film formed on a support layer made of crystalline polyester, where the light diffusing film comprises a crystalline polyester blended with 2 to 40 parts by mass of immiscible light diffusing agents.

On the other hand, Patent document 3 (International Publication WO2011/118449) discloses a thermoplastic liquid crystal polymer film with enhanced light reflection, where the film has 8 to 40 crystal domains per 10μm in the thickness direction of the film.

### RELATED DOCUMENTS

### Patent Documents

[Patent Document 1] JP Laid-open Patent Publication No. 2005-178056

[Patent Document 2] JP Laid-open Patent Publication No. 2007-293316

[Patent Document 3] International Publication W02011/118449

### SUMMARY OF THE INVENTION

Although the transparency of the film is improved in Patent Document 1, Patent Document 1 has a problem that decrease of haze value simultaneously occurs, resulting in reduction of light diffusibility. For example, where a film is used as a material for a circuit board, a certain transparency is desired in order to secure the flexibility of a design and the convenience at the time of processing, whereas the film desirably has a certain light diffusibility in order to maintain the secrecy of circuit design where the film is installed in a circuit board as end products.

In Patent document 2, on the premise of applications for back light unit of a liquid crystal display, light diffusibility of the film is realized by making the matrix material filled with particles which are immiscible with the matrix material. However, Patent Document 2 has a problem that where a highly multi-layered circuit board produced from a layer containing materials with different natures tends to generate smears during puncturing (for example, using laser and drill) at the time of electric conduction processing for interlayer connections, such smears cannot be uniformly removed in the desmear process, resulting in poor plating on the hole walls at a later processing. Therefore, since such films require complicated management for inorganic particles and insulating resin materials, which have appropriate processing characteristics different from each other, Patent Document 2 is industrially disadvantageous compared to the present invention from the viewpoints cost increase, etc.

In Patent document 3, although the films can enhance light reflection property by making many crystal domains layered in a thickness direction, the light transmittance of the film with such a structure is obstructed. Therefore, an object of the present invention is to provide a thermoplastic liquid crystal polymer molded body with high total light transmittance and very high haze value, as well as a metal-clad laminate and a circuit board both using the thermoplastic liquid crystal polymer molded body.

Liquid crystalline polyester resins usually comprise agglomerates of structures called microdomains (a kind of high order structure). Since the agglomerates typically contain voids and defects between microdomains, and the optical anisotropy of the microdomains are not continuous throughout the agglomerates, the agglomerates reflect light strongly at the interfaces between microdomains. Due to such a structure, it has been considered that it is difficult to make the liquid crystalline polyester resin transparent.

Based on the result of intensive studies to achieve the above objects, the inventors have found that light transmittance can be enhanced by controlling size of microdomains as well as interface between microdomains, while maintaining very-high haze value.

The inventors have further found that where the thermoplastic liquid crystal polymer molded body with such a controlled high order structure is used as multilayer structure, the thermoplastic liquid crystal polymer molded body exhibits not only improved adhesive strength with an object to be adhered, but also high heat resistance.

That is, the present invention may provide following preferred aspects.

A first aspect according to the present invention is a thermoplastic liquid crystalline polymer molded body having a haze value of 99% or higher, and a thermal expansion coefficient of 16 to 27 ppm/° C., and satisfying a correlation between a light absorption coefficient (ε) and a thickness (x) as:

ε≤0.21x^{-0.55}.

In the thermoplastic liquid crystal polymer molded body, the thermoplastic liquid crystal polymer may be selected from the group consisting of a polyester including repeating units derived from p-hydroxybenzoic acid and 6-hydroxy-2-naphthoic acid; a polyester including repeating units derived from 6-hydroxy-2-naphthoic acid, terephthalic acid, and p-amino phenol; a polyester including repeating units derived from p-hydroxybenzoic acid, 6-hydroxy-2-naphthoic acid, and terephthalic acid; a polyester including repeating units derived from 6-hydroxy-2-naphthoic acid, terephthalic acid, p-amino phenol, isophthalic acid, hydroquinone, and a naphthalene dicarboxylic acid; and a polyester including repeating units derived from p-hydroxybenzoic acid, terephthalic acid, and 4,4′-dihydroxybiphenyl.

The thermoplastic liquid crystal polymer molded body may have a shape of a film.

A second aspect according to the present invention is a metal-clad laminate in which the laminate comprises the thermoplastic liquid crystal polymer molded body in a shape of a film and a metal layer(s) bonded to at least one surface (one or both surfaces) of the molded body.

A third aspect according to the present invention is a circuit board comprising the metal-clad laminate in which the at least one metal layer is configured to have a circuit pattern.

The circuit board may be a multi-layered circuit board comprising at least one layer of the metal-clad laminate.

Any combination of at least two constructions, disclosed in the appended claims and/or the specification should be construed as included within the scope of the present invention. In particular, any combination of two or more of the appended claims should be equally construed as included within the scope of the present invention.

### EFFECTS OF THE INVENTION

The thermoplastic liquid crystal polymer molded body according to the present invention has a specific thermal expansion coefficient while having a high total light transmittance and very-high haze value. Accordingly, for example, at the time of processing multi-layer lamination of an electronic circuit board, high total light transmittance of the thermoplastic liquid crystal polymer molded body facilitates alignment of circuit wiring between layers so as to suppress misalignment of the circuit wiring, while high haze value of the thermoplastic liquid crystal polymer molded body enables to add functions such as secured secrecy of wiring and elements in a device, and reduction in light interference. Therefore, such thermoplastic liquid crystal polymer molded bodies are very useful as insulator materials. Further, thanks to flexible applicability for device design and improved designability, the thermoplastic liquid crystal polymer molded bodies are expected to be used for applications to electronic and optical materials, such as displays, photo sensors, anti-glare films, light instruments, and protective films for light polarizers. Furthermore, controlled microdomain size make the thermoplastic liquid crystal polymer molded bodies possible to enhance bonding property to an object to be bonded, and to improve heat resistance, so that the thermoplastic liquid crystal polymer molded bodies are very useful as insulator materials, such as electronic circuit boards.

### BRIEF DESCRIPTION OF THE DRAWINGS

FIG. 1 is a schematic cross-sectional view for illustrating a production process of a molded body, a metal-clad laminate, and a circuit board according to an embodiment of the present invention; and

FIG. 2 is a graph showing correlation between film thickness and light absorption coefficient in each of the films in Examples and Comparative Examples.

### DESCRIPTION OF THE EMBODIMENTS

The molded body according to the present invention is a molded body comprising a liquid crystal polymer (hereinafter referred to as a thermoplastic liquid crystal polymer) which shows an optically anisotropic melt phase, having an extremely high haze value of 99% or higher, and satisfies a correlation formula between a light absorption coefficient (ε) and a thickness (x) as:

ε≤0.21x^{-0.55}.

The shape of the molded body is not limited to a specific one, and may be, for example, a film shape (i.e., thermoplastic liquid crystal polymer film). The present invention may encompass a laminate (metal-clad laminate) comprising the molded body and a metal layer(s) laminated on at least one surface (one surface or both surfaces) of the molded body, and a circuit board comprising a conductor circuit on at least one surface of the molded body.

### Thermoplastic Liquid Crystal Polymer

A thermoplastic liquid crystal polymer used in the present invention is a polymer capable of forming an optically anisotropic melt phase. Examples of the thermoplastic liquid crystal polymer may include a thermoplastic liquid crystal polyester, or a thermoplastic liquid crystal polyester amide having an amide bond introduced thereto.

The thermoplastic liquid crystal polymer may also be a polymer obtained by further introducing, to an aromatic polyester or an aromatic polyester amide, an imide bond, a carbonate bond, a carbodiimide bond, or an isocyanate-derived bond such as an isocyanurate bond.

Specific examples of the thermoplastic liquid crystal polymer used in the present invention may include known thermoplastic liquid crystal polyesters and thermoplastic liquid crystal polyester amides obtained from compounds classified as (1) to (4) as exemplified in the following, and derivatives thereof. However, it is needless to say that, in order to form a polymer capable of forming an optically anisotropic melt phase, there is a suitable range regarding the combination of various raw-material compounds.

### (1) Aromatic or Aliphatic Diols (see Table 1 for Representative Examples)

TABLE 1
Chemical structural formulae of representative examples of
aromatic or aliphatic diols

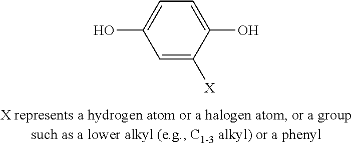

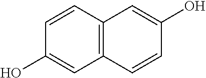 [SMILES: Oc1ccc2cc(O)ccc2c1]

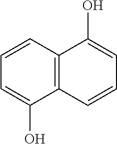 [SMILES: Oc1cccc2c(O)cccc12]

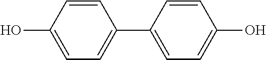 [SMILES: Oc1ccc(-c2ccc(O)cc2)cc1]

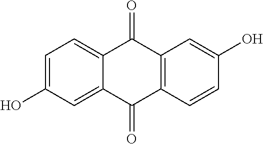 [SMILES: O=C1c2ccc(O)cc2C(=O)c2ccc(O)cc21]

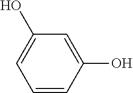

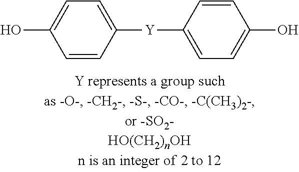

### (2) Aromatic or Aliphatic Dicarboxylic Acids (see Table 2 for Representative Examples)

TABLE 2
Chemical structural formulae of representative examples of
aromatic or aliphatic dicarboxylic acids

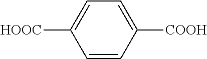 [SMILES: O=C(O)c1ccc(C(=O)O)cc1]

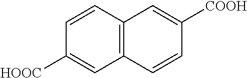 [SMILES: O=C(O)c1ccc2cc(C(=O)O)ccc2c1]

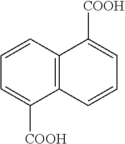 [SMILES: O=C(O)c1cccc2c(C(=O)O)cccc12]

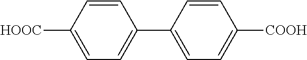 [SMILES: O=C(O)c1ccc(-c2ccc(C(=O)O)cc2)cc1]

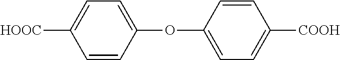 [SMILES: O=C(O)c1ccc(Oc2ccc(C(=O)O)cc2)cc1]

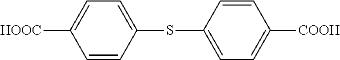 [SMILES: O=C(O)c1ccc(Sc2ccc(C(=O)O)cc2)cc1]

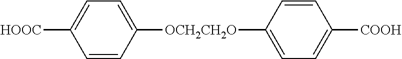

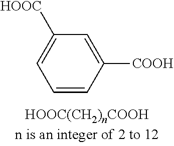 [SMILES: O=C(O)c1cccc(C(=O)O)c1]

### (3) Aromatic Hydroxycarboxylic Acids (see Table 3 for Representative Examples)

TABLE 3
Chemical structural formulae of representative examples of
aromatic hydroxycarboxylic acids

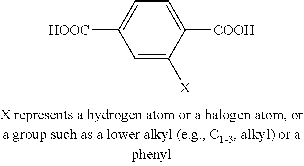

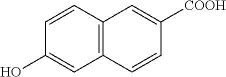 [SMILES: O=C(O)c1ccc2cc(O)ccc2c1]

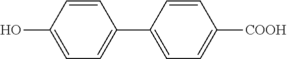 [SMILES: O=C(O)c1ccc(-c2ccc(O)cc2)cc1]

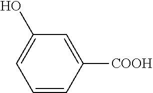

### (4) Aromatic Diamines, Aromatic Hydroxy Amines, and Aromatic Aminocarboxylic Acids (see Table 4 for Representative Examples)

TABLE 4
Chemical structural formulae of representative examples of aromatic
diamines, aromatic hydroxy amines, or aromatic aminocarboxylic acids

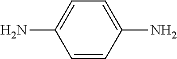

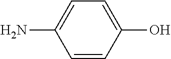

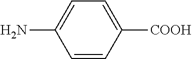

Representative examples of thermoplastic liquid crystal polymers obtained from these raw-material compounds may include copolymers having structural units shown in Tables 5 and 6.

TABLE 5
Representative examples (1) of thermoplastic liquid crystal polymer

| | |
|---|---|
| (A) | 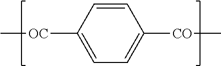 |
| | 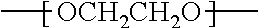 |
| | 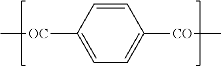 |
| (B) | 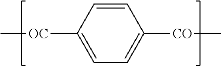 |
| | 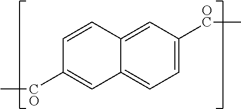 |
| | 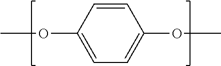 |
| (C) | 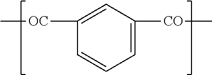 |
| | 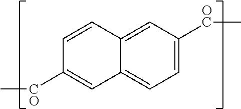 |
| | 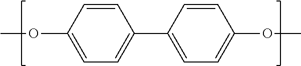 |
| (D) | 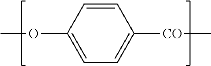 |
| | 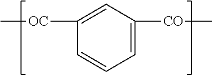 |
| | 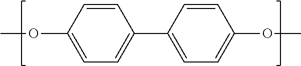 |
| (E) | 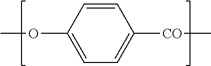 |
| | 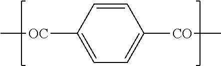 |
| | 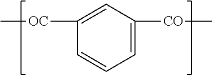 |
| | 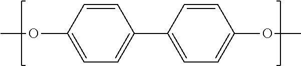 |
| (F) | 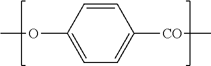 |
| | 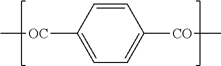 |
| | 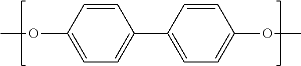 |
| | 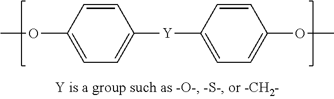 |
| (G) | 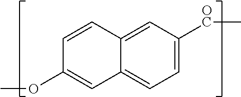 |
| | 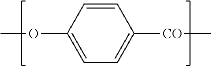 |
| (H) | 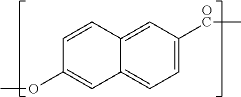 |
| | 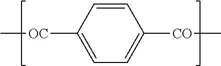 |
| | 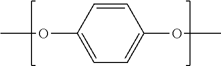 |
| (I) | 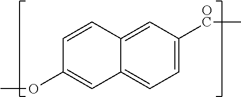 |
| | 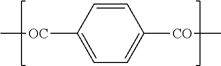 |
| | 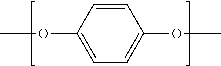 |
| | 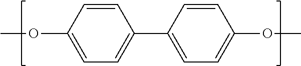 |
| (J) | 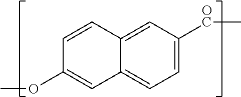 |
| | 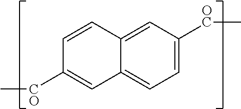 |
| | 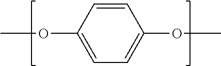 |

TABLE 6
Representative examples (2) of thermoplastic liquid crystal polymer

| | |
|---|---|
| (K) | 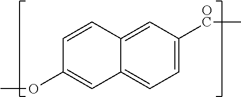 |
| | 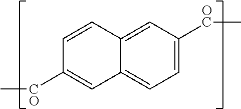 |
| | 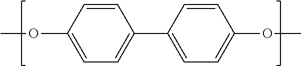 |
| (L) | 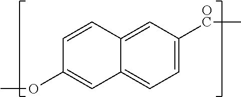 |
| | 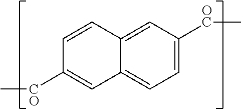 |
| | 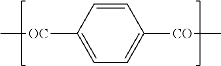 |
| | 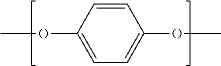 |
| (M) | 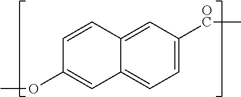 |
| | 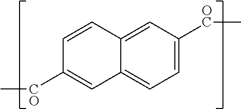 |
| | 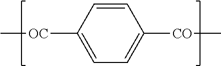 |
| | 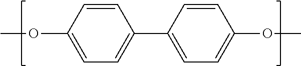 |
| (N) | 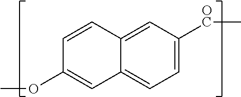 |
| | 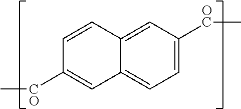 |
| | 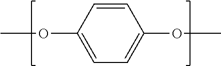 |
| | 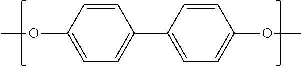 |
| (O) | 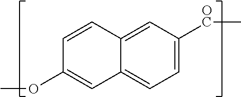 |
| | 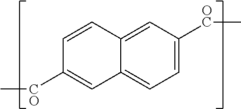 |
| | 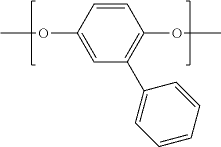 |
| | 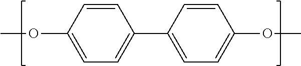 |
| (P) | 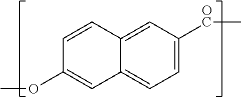 |
| | 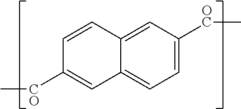 |
| | 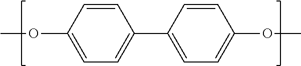 |
| | 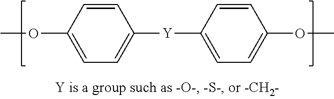 |
| (Q) | 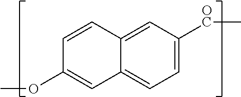 |
| | 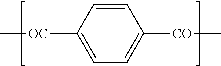 |
| | 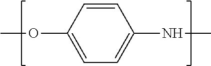 |

Of these copolymers, preferable polymers include at least p-hydroxybenzoic acid and/or 6-hydroxy-2-naphthoic acid as repeating units, and more preferred polymers may include:

a polymer (i) having repeating units of p-hydroxybenzoic acid and 6-hydroxy-2-naphthoic acid; and

a copolymer (ii) having repeating units of
at least one aromatic hydroxycarboxylic acid selected from a group consisting of p-hydroxybenzoic acid and 6-hydroxy-2-naphthoic acid,
at least one aromatic diol and/or at least one hydroxyamine, and
at least one aromatic dicarboxylic acid.

Where the thermoplastic liquid crystal polymer is a copolymer comprising repeating units with p-hydroxybenzoic acid (A) and 6-hydroxy-2-naphthoic acid (B), the mole ratio (A)/(B) is preferably (A)/(B)=10/90 to 90/10, more preferably 50/50 to 90/10, further preferably 75/25 to 90/10, still more preferably 75/25 to 85/15, and particularly preferably 77/23 to 80/20.

For example, in the case where the copolymer (i) comprises a thermoplastic liquid crystal polymer having repeating units of at least p -hydroxybenzoic acid (A) and 6-hydroxy-2-naphthoic acid (B), the thermoplastic liquid crystal polymer may have a mole ratio (A)/(B) of preferably about (A)/(B) =10/90 to 90/10, more preferably about (A)/(B)=15/85 to 85/15, and further preferably about (A)/(B)=20/80 to 80/20.

Furthermore, in the case where the copolymer (ii) comprises a thermoplastic liquid crystal polymer having repeating units of: at least one aromatic hydroxycarboxylic acid (C) selected from a group consisting of p -hydroxybenzoic acid and 6-hydroxy-2-naphthoic acid; at least one aromatic diol (D) selected from a group consisting of 4,4′-dihydroxybiphenyl, hydroquinone, phenylhydroquinone, and 4,4′-dihydroxydiphenyl ether; and at least one aromatic dicarboxylic acid (E) selected from a group consisting of terephthalic acid, isophthalic acid, and 2,6-naphthalene dicarboxylic acid, the thermoplastic liquid crystal polymer may have a mole ratio of about aromatic hydroxycarboxylic acid (C):aromatic diol (D):aromatic dicarboxylic acid (E)=30 to 80:35 to 10:35 to 10, more preferably about (C):(D):(E)=35 to 75:32.5 to 12.5:32.5 to 12.5, and further preferably about (C):(D):(E)=40 to 70:30 to 15:30 to 15.

Furthermore, the thermoplastic liquid crystal polymer may have a mole ratio of a repeating structural unit derived from 6-hydroxy-2-naphthoic acid to the aromatic hydroxycarboxylic acids (C), for example, of 85 mol % or higher, preferably 90 mol % or higher, and more preferably 95 mol % or higher. The liquid crystal polymer may have a mole ratio of a repeating structural unit derived from 2,6-naphthalene dicarboxylic acid to the aromatic dicarboxylic acids (E), for example, of 85 mol % or higher, preferably 90 mol % or higher, and more preferably 95 mol % or higher.

The aromatic diol (D) may include repeating structural units (D1) and (D2) derived from two different aromatic diols each selected from a group consisting of hydroquinone, 4,4′-dihydroxy biphenyl, phenylhydroquinone, and 4,4′-dihydroxydiphenyl ether. In such a case, the two aromatic diols may have a mole ratio (D1)/(D2)=23/77 to 77/23, more preferably 25/75 to 75/25, and further preferably 30/70 to 70/30.

Furthermore, the liquid crystal polymer may have a mole ratio of a repeating structural unit derived from an aromatic diol (D) to a repeating structural unit derived from an aromatic dicarboxylic acid (E) of preferably (D)/(E)=9⁵/100 to 100/95. Deviation from this range may tend to result in a low degree of polymerization and deterioration in mechanical strength.

In the above-described thermoplastic liquid crystal polymer, most preferably thermoplastic liquid crystal polymer for molded body may be used by selecting from the group consisting of a polyester including repeating units derived from p-hydroxybenzoic acid and 6-hydroxy-2-naphthoic acid; a polyester including repeating units derived from 6-hydroxy-2-naphthoic acid, terephthalic acid, and p-amino phenol; a polyester including repeating units derived from p-hydroxybenzoic acid, 6-hydroxy-2-naphthoic acid, and terephthalic acid; a polyester including repeating units derived from 6-hydroxy-2-naphthoic acid, terephthalic acid, p-amino phenol, isophthalic acid, hydroquinone, and a naphthalene dicarboxylic acid; and a polyester including repeating units derived from p-hydroxybenzoic acid, terephthalic acid, and 4,4′-dihydroxybiphenyl.

It should be noted that, in the present invention, optical anisotropy in a molten state can be determined by, for example, placing a sample on a hot stage, heating the sample at an elevating temperature under nitrogen atmosphere, and observing light transmitted through the sample.

A preferred thermoplastic liquid crystal polymer has a melting point (hereinafter, referred to as Tm₀) in a range of, for example, from 200° C. to 360° C., preferably from 240° C. to 350° C., more preferably from 260° C. to 330° C., and more preferably from 290° C. to 330° C. The melting point may be determined by observing thermal behavior of a thermoplastic liquid crystal polymer sample using a differential scanning calorimeter. That is, a melting point of a thermoplastic liquid crystal polymer sample may be determined by subjecting the sample to temperature elevation at a rate of 10° C./min to completely melt the thermoplastic liquid crystal polymer sample, then to cooling the molten polymer at a rate of 10° C./min to 50° C., and again to temperature elevation at a rate of 10° C./min to determine the position of an endothermic peak that occurs during the second temperature elevation as the melting point of the thermoplastic liquid crystal polymer sample.

As long as the advantageous effect of the present invention is not spoiled, to the thermoplastic liquid crystal polymer, may be added any thermoplastic polymer such as a polyethylene terephthalate, a modified polyethylene terephthalate, a polyolefin, a polycarbonate, a polyarylate, a polyamide, a polyphenylene sulfide, a polyether ether ketone, and a fluorine-containing resin; and/or various additives; fillers, and others.

One embodiment of the thermoplastic liquid crystal polymer employed in the present invention may preferably exclude additives and fillers. By excluding a material different from the thermoplastic liquid crystal polymer, where smears generate during puncturing (for example, laser and drill) at the time of electric conduction processing for interlayer connections, such smears can be uniformly removed in the desmear process, resulting in avoiding poor plating on the hole walls at a later processing. Therefore, the thermoplastic liquid crystal polymer molded body employed in the present invention may be preferably a thermoplastic liquid crystal polymer film excluding additives and fillers. a highly multi-layered circuit board produced from a layer containing materials with different natures generates smears

### Molded Body

The shape of the molded body according to the present invention is not limited to a specific one, and may be processed into an arbitrary shape depending on intended usage of the thermoplastic liquid crystal polymer. For example, the molded body may have a shape of a film. The thermoplastic liquid crystal polymer film in a shape of a film, i.e., thermoplastic liquid crystal polymer film, can be obtained, for example, by extruding a molten kneaded material of the above-described thermoplastic liquid crystal polymer. Although any extrusion methods may be used, well-known methods such as a T-die method and an inflation method are industrially advantageous. In particular, the inflation method can apply stresses to an extruded polymer not only in a machine processing direction of a thermoplastic liquid crystal polymer film (hereinafter referred to as MD), but also in a transverse direction (hereinafter, abbreviated as TD) perpendicular to the MD so as to stretch uniformly both in MD and TD, resulting in a thermoplastic liquid crystal polymer film having controlled properties such as molecular orientation and dielectric characteristics in both the MD and TD.

For example, in the extrusion molding by means of a T-die method, a molten polymer sheet extruded from a T-die may be stretched in the MD and TD at the same time, alternatively a molten polymer sheet extruded from a T-die may be stretched in sequence, first in the MD and then the TD.

Also, in the extrusion molding by an inflation method, a tubular sheet being melt-extruded from an annular die may be drawn with a predetermined draw ratio (corresponding to a stretching ratio in MD) and a predetermined blow ratio (corresponding to a stretching ratio in TD).

As the stretching ratios carried out in such extrusion molding, a stretching ratio in the MD (or draw ratio), may be, for example, about 1.0 to 10, preferably about 1.2 to 7, and more preferably 1.3 to 7. A stretching ratio in the TD (or blow ratio), may be, for example, about 1.5 to 20, preferably about 2 to 15, and still more preferably about 2.5 to 14.

If necessary, known or common heat treatment may be carried out to adjust a melting point and/or a thermal expansion coefficient of a thermoplastic liquid crystal polymer film to have a thermal expansion coefficient in a desired range. Heat treatment conditions can be appropriately determined depending on the purpose. The heat treatment may be carried out by heating for hours at a temperature of, for example, (Tm₀−10)° C. or higher, wherein Tm₀ denotes a melting point of a liquid crystal polymer, for example, about (Tm₀−10)° C. to (Tm₀+30)° C., preferably about Tm₀° C. to (Tm₀+20)° C. to increase a melting point (Tm) of the thermoplastic liquid crystal polymer film.

The melting point (Tm) of the thermoplastic liquid crystal polymer film may be selected in a range from about 270° C. to 380° C., preferably about 280° C. to 370° C. and more preferably about 290° C. to 360° C. The melting point may be determined by observing thermal behavior of a thermoplastic liquid crystal polymer film sample using a differential scanning calorimeter. That is, a melting point (Tm) of a thermoplastic liquid crystal polymer film sample may be obtained by subjecting the sample to temperature elevation at a rate of 10° C./min to determine the position of an endothermic peak that occurs during the temperature elevation as the melting point of the thermoplastic liquid crystal polymer film sample.

The thermoplastic liquid crystalline polymer film may have an appropriate thickness depending on use. For example, where the film is used as an electrical isolation layer of a multi-layer circuit board, the film may have a thickness of 10 to 500 μm, preferably 15 to 250 μm, more preferably 25 to 180 μm, and further preferably 25 to 100 μm.

The thermoplastic liquid crystalline polymer molded body according to the present invention is adjusted to have, on the plane of the molded body, a thermal expansion coefficient of, for example, 16 to 27 ppm/° C., preferably 17 ppm/° C. and higher, and more preferably 18 ppm/° C. and higher. The thermal expansion coefficient may be preferably 25 ppm/° C. or lower, more preferably 23 ppm/° C. or lower, and still more preferably 20 ppm/° C. or lower. The thermal expansion coefficient can be measured, for example, by the TMA method.

Although thermoplastic liquid crystal polymers generally exhibit high haze values, the thermoplastic liquid crystal polymer molded bodies according to the present invention have improved total light transmittances compared to conventional products while maintaining the high haze values. That is, the thermoplastic liquid crystal polymer molded body (for example, thermoplastic liquid crystal polymer film) according to the present invention is one having a haze value of 99% or higher, and satisfying a correlation formula between a light absorption coefficient (ε) and a thickness (x) as:

ε≤0.21x^{-0.55}.

For example, the above-mentioned optical characteristics can be imparted to a molded body by once processing a thermoplastic liquid crystal polymer into a predetermined shape, and then subjecting it to a predetermined heat treatment. The heat treatment is preferably carried out at a temperature higher than a melting point (Tm) of a molded body (thermoplastic liquid crystal polymer film), for example, a temperature higher than the melting point Tm by 20° C. or more, and preferably a temperature higher than the melting point Tm by 20 to 40° C. The period for heat treatment may be at least one second, and preferably 4 seconds or longer. On the other hand, too long heat treatment may cause degradation of the thermoplastic liquid crystal polymer, so that the period for heat treatment may be preferably 500 seconds or shorter, and more preferably 400 seconds or shorter.

It is considered that the above-described heat treatment can impart desired optical characteristic for the following reasons. On one hand, since the thermoplastic liquid crystal polymer film still comprises a multi-domain structure, it preserves the haze value of 99% or higher. On the other hand, transparency of the film is improved due to the growth of domain size caused by the heat treatment and reduction of defects caused by relaxation of strain during the molding process. It should be noted that the thermoplastic liquid crystal polymer film may be heat-treated after forming a metal layer(s) on one surface or both surfaces of the film. After the heat treatment, such a laminate may be used as the below-described metal-clad laminate, or may be used for other applications after delaminating the metal layer.

### Metal-Clad Laminate

The laminate according to the present invention is a laminate (i.e., a metal-clad laminate) comprising the thermoplastic liquid crystal polymer molded body (for example, thermoplastic plastic liquid crystal polymer film) and a metal layer(s) at least one surface of the thermoplastic liquid crystal polymer molded body.

The molded body may be, for example, a metal-clad laminate comprising the thermoplastic liquid crystal polymer film and a metal layer(s) on at least one surface of the thermoplastic liquid crystal polymer film, i.e., single-sided metal-clad laminate or double-sided metal-clad laminate.

Although a metal layer can suitably comprise any metal depending on the purposes, copper, nickel, cobalt, aluminum, gold, tin, chromium, and others are preferably used. The thickness of the metal layer may be 0.01 to 200 μm, preferably 0.1 to 100 μm, more preferably 1 to 80 μm, and particular preferably 2 to 50 μm.

The method for laminating a metal layer is not limited to a specific one, and, for example, metal foil (for example, copper foil) may be press-bonded to a thermoplastic liquid crystal polymer film using roll pressing device, via roll-to-roll system, or may be press-bonded using double belt press equipment or vacuum heat-press equipment, or other equipment. Alternatively, a surface of the thermoplastic liquid crystal polymer film may be subjected to vacuum deposition to form a deposition layer, and then a metal layer may be formed on the deposition layer by electrolytic plating.

### Circuit Board

Circuit board, which is one embodiment of the present invention, can be formed from a metal-clad laminate comprising a thermoplastic liquid crystal polymer molded body according to the present invention as a substrate. The circuit board comprises a circuit part(s) provided on one surface or both surfaces of the metal layers. The circuit may be formed by a known subtractive method, additive method, semi-additive method, and others. The thickness of the circuit (metal layer) may be, for example 10 to 14 μm, and preferably 11 to 13 μm. The circuit board may be from the metal-clad laminate as described above, or may be a multilayer circuit board which comprises the metal-clad laminate as described above and another layer.

It should be noted that the circuit board may be configured to have a through-hole, if necessary, by various known or commonly-used production processes. In such a case, the circuit board, may be provided with a through-hole plating layer. The thickness of the circuit (metal layer) with the through-hole plating layer may be, for example, 20 to 40 μm, and preferably 25 to 35 μm.

### Method for Producing Thermoplastic Liquid Crystal Polymer Molded Body

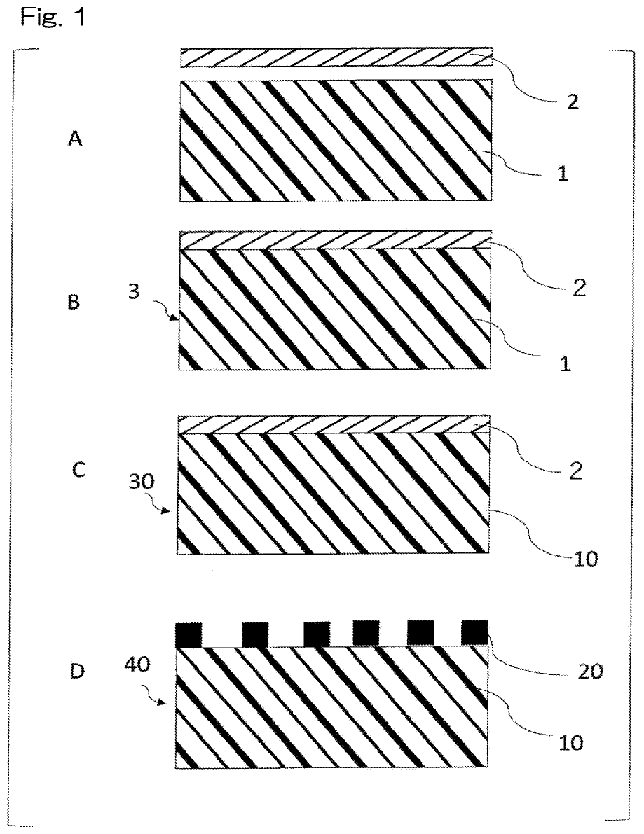

Hereinafter, referring to FIG. 1, as one example, a method for producing a molded body, a metal-clad laminate, and a circuit board, all according to one embodiment of the present invention will be described. It should be noted that. FIG. 1 is a schematic sectional view only for explanation, and the thickness ratio, width, etc. of the materials do not reflect their actual size.

### A. Preparation Process

First a thermoplastic liquid crystal polymer film 1 and a metal foil 2 for forming a metal layer are prepared.

### B. Lamination Process

Then the thermoplastic liquid crystal polymer film 1 and the metal foil 2 are press-bonded by heat-pressing to form a laminated precursor 3.

### C. Heat Treatment Process

Then, the laminated precursor 3 is heat-treated at a temperature higher than the melting point of the thermoplastic liquid crystal polymer film 1, for example, a temperature higher than the melting point by 20° C. or higher, under an inert atmosphere, preferably nitrogen gas, to improve total light transmittance of the liquid crystal polymer film 1 to obtain a metal-clad laminate 30, which is a laminate according to the present invention, in which the film-shaped liquid crystal polymer molded body 10 and the metal foil 2 are laminated. In addition, where continuous heating is carried out, depending on the thickness or width of the laminated precursor, an appropriate load or tension may be set in order to make the laminate under continuous heat treatment stable. From the viewpoint of dimensional stability, the laminated precursor 3 may be preferably heat-treated in the condition of horizontally placed without applying load and/or tension.

### D. Circuit Processing

Thereafter, the circuit processing may be carried out on the metal foil 2 so as to produce a circuit board 40 having a circuit pattern 20.

The conditions for each process may be determined in accordance with the above explanation. The metal-clad laminate 30 after heat treatment process may be subjected to etching or others to remove the metal foil 2 so as to obtain a film-shaped thermoplastic liquid crystal molded body 10 to be used for other applications. In addition, in FIG. 1, a metal foil 2 is press-bonded on one surface of the thermoplastic liquid crystal polymer film 1. Alternatively, both surfaces of the thermoplastic liquid crystal polymer film may be press-bonded with metal foils 2.

In the above-mentioned lamination process B, although the metal foil 2 may be suitably determined depending on purposes, there may be exemplified as foils of metals such as copper, nickel, cobalt, aluminum, gold, tin, and chromium. It is preferred to use a copper foil and an aluminum foil, and more preferred to use a copper foil.

In the above-mentioned heat treatment process C, the heat treatment temperature may be, with respect to the melting point (Tm) of thermoplastic liquid crystal polymer film 1, may be preferably at Tm+10° C. or higher, more preferably at Tm+15° C. or higher, and still more preferably at Tm+20° C. or higher. The heat treatment temperature may be preferably at Tm+40° C. or lower, more preferably at Tm+35° C. or lower, and still more preferably at Tm+30° C. or lower. The heat treatment period may be preferably 1 second or longer, more preferably 2 seconds or longer, still more preferably 3 seconds or longer, and further preferably 4 seconds or longer. The heat treatment period may be preferably 500 seconds or shorter, more preferably 400 seconds or shorter, still more preferably 350 seconds or shorter, and further preferably 300 seconds or shorter.

### EXAMPLES

Hereinafter, the present invention will be described in more detail with reference to the Examples. However, the present invention will not be limited by the Examples whatsoever.

The followings will describe each valuation method of the thermoplastic liquid crystal polymer films adopted in the Examples and Comparative Examples below.

### (1) Film Thickness

The film thickness of a sample was calculated as an average of measurements taken at 10 locations at equal interval of 1 cm in traverse direction (TD) using a digital thickness gauge (manufactured by Mitutoyo Corporation).

### (2) Total Light Transmittance

The total light transmittance was measured in accordance with JIS K 7136 using “HAZEMETER, HM-150” (manufactured by MURAKAMI COLOR RESEARCH LABORATORY).

### (3) Haze

The haze was measured in accordance with JIS K 7136 using “HAZEMETER, HM-150” (manufactured by MURAKAMI COLOR RESEARCH LABORATORY).

### (4) Light Absorption Coefficient

The light absorption coefficient (ε) was calculated by the Lambert-Taubert formula as ε=−logR/x from the measured total light transmittance (R: 100R in percentage) and the film thickness (x).

### (5) Coefficient of Thermal Expansion (CTE) of Film

The thermal expansion coefficient of a film was measured using a thermomechanical analyzer (TMA). The film was subjected to temperature elevation from 25° C. to 200° C. at a rate of 5° C./min, then to cooling to 30° C. at a rate of 20° C./min, and again to temperature elevation at a rate of 5° C./min to measure thermal expansion coefficients between 30° C. and 150° C. It should be noted that the measurements were performed in the machine direction (MD) and in the transverse direction (TD) of the film, and the average value was evaluated as thermal expansion coefficient of the film.

### (6) Dimensional Change Rate of Copper-Clad Laminate

The dimensional change rate of copper-clad laminate was measured according to IPC-TM-6502.2.4. Heating condition was 150° C.×30 minutes to measure a dimensional change rate of the sample between before and after heating (%).

### (7) Bonding Strength of Copper-Clad Laminate

In accordance with JIS C5016-1994, peeling strength of a copper foil was measured using a tensile test machine (digital force gauge FGP-2 produced by NIDEC-SHIMPO CORPORATION) by peeling the copper foil from the copper-clad laminate in the 90-degree direction at a speed of 50 mm/min. The obtained value was regarded as bonding strength.

### (8) Solder Heat Resistance

Solder heat resistance was measured by investigating a retention time for a film surface to keep the original appearance on a molten solder bath maintained at a predetermined temperature. That is, the laminate was placed on the molten solder bath maintained at 300° C. to visually observe change in appearance such as blister generation on film surface and film deformation. Table 7 shows results of the evaluation: “Good” where no blister or deformation was observed for 60 seconds after placing the solder bath, and “Poor” where blister or deformation occurred for 60 seconds after placing the solder bath.

### (9) Visibility

A sample was placed on a paper with printed patterns of stripes (0.1 mm intervals) and patterns of circulars and squares of different sizes (0.5 to 5 mm in diameter or width) to observe recognizable patterns as the minimum size. The minimum size of the recognized pattern is shown in Table below.

### REFERENCE EXAMPLES

A thermoplastic liquid crystal polymer of 6-hydroxy-2-naphthoic acid and p-hydroxybenzoic acid copolymer having a melting point of 310° C., as a raw material of a thermoplastic liquid crystal polymer molded body, was melt-kneaded using mono-axial extruder to be melt-extruded from a circular die of the inflation apparatus having a die diameter of 33.5 mm, and a die slit interval of 500 μm to obtain thermoplastic liquid crystal polymer films having film thicknesses of 25 μm to 100 μm. The thermoplastic liquid crystal polymer film having film thicknesses of 25 μm had a melting point of 310° C., a total light transmittance of 26.8%, a haze value of 99.6%, and a light absorption coefficient of 0.053/μm.

Each of thus-obtained thermoplastic liquid crystal polymer films with different thicknesses of 25 μm to 100 μm was press-bonded with a cupper foil “JXEFL-BHM” manufactured by JX Nippon Mining & Metals Corporation for 5 minutes at a temperature of 300° C. under a pressure 4.0 MPa to produce a copper-clad laminate.

### Examples 1 to 5

Each of the copper clad laminates obtained in the Reference Examples was placed horizontally in a hot air dryer at 330° C. under a nitrogen atmosphere to be heat-treated for periods shown in Table 7. Then, the copper foil was removed with ferric chloride solution to obtain thermoplastic liquid crystal polymer films.

### Example 6

A double-sided copper-clad laminate was prepared by laminating copper foils of similar type on both surfaces of the thermoplastic liquid crystal polymer film with a thickness of 50 μm which had been obtained in the same manner as the Reference Example. The copper clad laminate was placed horizontally in a hot air dryer at 330° C. under a nitrogen atmosphere to be heat-treated for 4 seconds. Then, the copper foils were removed with ferric chloride solution to obtain a thermoplastic liquid crystal polymer film.

### Comparative Examples 1 to 4

Copper-clad laminates were produced by press-bonding films “VECSTAR” (registered trademark) CTQ with thicknesses of 25 to 100 μm, manufactured by Kuraray Co., Ltd. and foils “JXEFL-BHM” manufactured by JX

Nippon Mining & Metals Corporation, respectively, at a temperature of 300° C. under a pressure of 4.0 MPa for 5 minutes. The copper foils were then removed with ferric chloride solution to obtain thermoplastic liquid crystal polymer films.

### Comparative Example 5

The copper-clad laminate obtained in Reference Example was heat-treated at a temperature and period shown in Table 7. The copper foil was then removed with ferric chloride solution to obtain a thermoplastic liquid crystal polymer film.

TABLE 7

| | | | | | | | Com. | Com. | Com. | Com. | Com. |
|---|---|---|---|---|---|---|---|---|---|---|---|
| | Ex. 1 | Ex. 2 | Ex. 3 | Ex. 4 | Ex. 5 | Ex. 6 | Ex. 1 | Ex. 2 | Ex. 3 | Ex. 4 | Ex. 5 |
| Thickness (μm) | 25 | 25 | 50 | 50 | 100 | 50 | 25 | 75 | 100 | 50 | 50 |
| Melting point | 310 | 310 | 310 | 310 | 310 | 310 | 310 | 310 | 310 | 310 | 310 |
| (° C.) | | | | | | | | | | | |
| Heat treatment | 330 | 330 | 330 | 330 | 330 | 330 | — | — | — | 310 | 315 |
| temp. (° C.) | | | | | | | | | | | |
| Heat treatment | 4 | 300 | 4 | 300 | 4 | 4 | — | — | — | 4 | 300 |
| period (sec.) | | | | | | | | | | | |
| Total light | 45.8 | 54.9 | 34.5 | 41.2 | 23.4 | 36.7 | 36.9 | 20.5 | 16.2 | 25.0 | 28.6 |
| transmittance (%) | | | | | | | | | | | |
| Haze (%) | 99.9 | 99.9 | 99.9 | 99.9 | 99.9 | 99.7 | 99.8 | 99.5 | 99.9 | 99.9 | 99.7 |
| Light absorption | 0.03124 | 0.02399 | 0.02128 | 0.01773 | 0.01452 | 0.02005 | 0.03988 | 0.02113 | 0.01820 | 0.02773 | 0.02504 |
| coefficient (/° C.) | | | | | | | | | | | |
| CTE (ppm/° C.) | 20 | 26 | 20 | 25 | 19 | 20 | 16 | 16 | 16 | 2 | 6 |
| Dimensional | 0.02 | −0.14 | 0.03 | −0.13 | 0.04 | 0.01 | 0.02 | 0.04 | 0.06 | 0.41 | 0.20 |
| change rate (%) | | | | | | | | | | | |
| Bonding strength | 0.8≤ | 0.8≤ | 0.8≤ | 0.8≤ | 0.8≤ | 0.8≤ | 0.4 | 0.4 | 0.5 | 0.4 | 0.4 |
| (N/mm) | | | | | | | | | | | |
| Solder resistance | Good | Good | Good | Good | Good | Good | Poor | Poor | Poor | Poor | Poor |
| Transmittant | 0.1 | 0.1 | 0.5 | 0.5 | 1 | 0.5 | 0.5 | — | 2 | 1 | 1 |
| visibility (mm) | | | | | | | | | | | |

### Comparative Examples 6 and 7

In addition to those shown in Table 7, as Comparative Examples 6 and 7, each of the metal-clad laminates in which a cupper foil was laminated to the thermoplastic liquid crystal polymer film 25 μm in thickness was placed horizontally in a hot air dryer at 330° C. under a nitrogen atmosphere for 600 seconds (Comparative Example 6) and for 1800 seconds (Comparative Example 7). The copper foils were then removed with ferric chloride solution to obtain thermoplastic liquid crystal polymer films. When the thermoplastic liquid crystal polymer films were measured, the total light transmittance values of these films were lower than that in Example 2. Further, the films in Comparative Examples 6 and 7 were discolored into yellow compared to the films obtained in Examples 1 to 5. In addition, the coefficient of thermal expansion of the films in Comparative Examples 6 and 7 could not be controlled within a predetermined range.

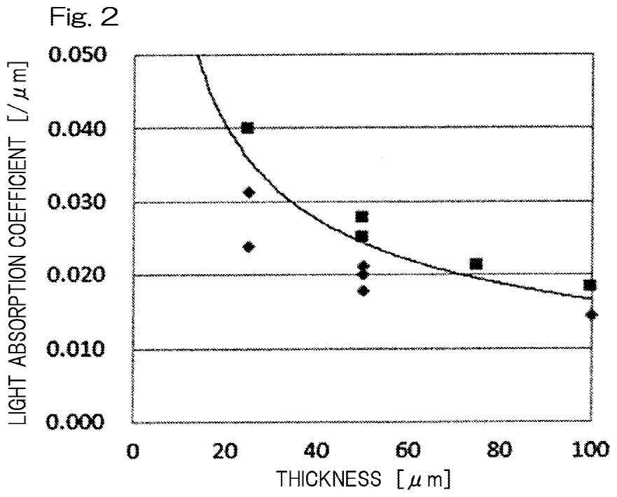

With respect to Examples 1 to 6 and Comparative Examples 1 to 5,FIG. 2 shows a scatter plot in which light absorption coefficient values and thickness values thereof are plotted as Y axis and as X axis, respectively. FIG. 2 reveals that the curve of ε=0.21x^{-0.55} forms a border distribution between Examples of the diamond shape dots and Comparative Examples of the square dots.

As shown in Table 7, the thermoplastic liquid crystal polymer molded bodies in Examples which passed through the heat treatment process have higher light transmittance and improved transmission visibility due to lower light absorption coefficients compared to those of Comparative Examples with the same thickness. Accordingly, Table 7 shows that the laminates with molded materials of specifically highly structure have high bonding strength and improved heat resistance. On the other hand, the thermoplastic liquid crystal polymer molded bodies in Comparative Examples 1 to 5, without passing through heat treatment, or with passing through heat treatment at low temperatures, indicate high haze values, but lower light transmittance and transmission visibility compared with respective Examples with the same thicknesses, respectively. In Comparative Examples 4 and 5, the thermal expansion coefficients of films fail to be controlled in the predetermined range.

### INDUSTRIAL APPLICABILITY

The thermoplastic liquid crystal polymer molded bodies according to the present invention have high total light transmittance and very-high haze values, and are applicable to conventionally used multi-layer circuit board, insulators for electronic circuit boards, reinforcing boards of flexible circuit boards, cover films for circuit, as well as to diffusion boards for displays and light equipment which require flexible applicability for device design and improved designability. Further, controlled microdomain size of the thermoplastic liquid crystal polymer molded body makes it possible to improve bonding property to an object to be bonded, as well as heat resistance. Accordingly, the thermoplastic liquid crystal polymer molded bodies are advantageously useful as insulator materials for electronic circuit boards and others.

Although the preferred embodiments of the present invention have been described, various additions, modifications, or deletions may be made without departing from the scope of the invention. Accordingly, such variants are included within the scope of the present invention.

### REFERENCE NUMERALS

1 Thermoplastic liquid crystal polymer film

2 Metal foil

3 Laminated precursor

10 Film-shaped thermoplastic liquid crystal polymer molded body

20 Circuit pattern

30 Metal-clad laminate

40 Circuit board

What is claimed is:

1. A thermoplastic liquid crystal polymer molded body having
a haze value of 99% or higher, and
a thermal expansion coefficient of 16 to 27 ppm/° C., and
satisfying a correlation between a light absorption coefficient (ε) and a thickness (x) as:
ε≤0.21x^{-0.55}.

2. The thermoplastic liquid crystal polymer molded body according to claim 1, wherein the thermoplastic liquid crystal polymer is selected from the group consisting of
a polyester including repeating units derived from p-hydroxybenzoic acid and 6-hydroxy-2-naphthoic acid;
a polyester including repeating units derived from p-hydroxybenzoic acid, 6-hydroxy-2-naphthoic acid, and terephthalic acid;
a polyester including repeating units derived from 6-hydroxy-2-naphthoic acid, terephthalic acid, and p-amino phenol;
a polyester including repeating units derived from 6-hydroxy-2-naphthoic acid, terephthalic acid, p-amino phenol, isophthalic acid, hydroquinone, and a dicarboxylic acid;
and a polyester including repeating units derived from p-hydroxybenzoic acid, terephthalic acid, and 4,4′-dihydroxybiphenyl.

3. A thermoplastic liquid crystal polymer molded body according to claim 1, having a shape of a film.

4. A metal-clad laminate comprising
the thermoplastic liquid crystal polymer molded body in a shape of a film as recited in claim 3,
and a metal layer(s) layered on at least one surface of the molded body.

5. A circuit board comprising the metal-clad laminate as recited in claim 4, wherein the at least one metal layer is configured to have a circuit pattern.

6. A multi-layered circuit board comprising at least one layer of the metal-clad laminate as recited in claim 4.
